(19) United States
(12) Patent Application Publication
(10) Pub. No.: US 2024/0274344 A1
(43) Pub. Date: Aug. 15, 2024

(54) INDUCTOR COMPONENT

(71) Applicant: Murata Manufacturing Co., Ltd., Kyoto-fu (JP)

(72) Inventor: Kenichi TANI, Nagaokakyo-shi (JP)

(73) Assignee: Murata Manufacturing Co., Ltd., Kyoto-fu (JP)

(21) Appl. No.: 18/543,926

(22) Filed: Dec. 18, 2023

(30) Foreign Application Priority Data
Feb. 10, 2023 (JP) 2023-019440

(51) Int. Cl. H01F 27/28; H01F 17/00; H01F 27/32

(52) U.S. Cl. CPC H01F 27/2804; H01F 17/0013; H01F 27/323

(57) ABSTRACT

An inductor component including an element body, a coil provided in the element body and wound along an axis, and a first outer electrode and a second outer electrode that are provided on the element body and that are electrically connected to the coil. The element body includes a plurality of insulation layers. The coil includes a plurality of coil wiring layers stacked along directions of the axis. The coil wiring layers are each interposed between the insulation layers. At least one of the coil wiring layers includes a first surface positioned in one of the directions of the axis and a second surface positioned in the other of the directions of the axis. At least one of the first surface and the second surface includes a recessed portion.

### CROSS-REFERENCE TO RELATED APPLICATION

This application claims benefit of priority to Japanese Patent Application No. 2023-019440, filed Feb. 10, 2023, the entire content of which is incorporated herein by reference.

### BACKGROUND

### Technical Field

The present disclosure relates to an inductor component.

### Background Art

A conventional inductor component is disclosed in Japanese Unexamined Patent Application Publication No. 5-36532. According to Japanese Unexamined Patent Application Publication No. 5-36532, the inductor component includes an element body and a coil provided in the element body and wound along an axis, the element body includes a plurality of insulation layers, the coil includes a plurality of coil wiring layers stacked along a direction of the axis, and the coil wiring layers are each interposed between the insulation layers.

### SUMMARY

In such an inductor component as the conventional inductor component, however, there has been a fear that separation of the coil wiring layers and the insulation layers may be caused by thermal stresses or bending stresses.

Therefore, the present disclosure provides an inductor component by which reduction in the separation of the coil wiring layers and the insulation layers has been achieved.

An inductor component according to an aspect of the present disclosure includes an element body, a coil provided in the element body and wound along an axis, and a first outer electrode and a second outer electrode that are provided on the element body and that are electrically connected to the coil. The element body includes a plurality of insulation layers. The coil includes a plurality of coil wiring layers stacked along directions of the axis. The coil wiring layers are each interposed between the insulation layers. At least one of the coil wiring layers includes a first surface positioned in one of the directions of the axis and a second surface positioned in the other of the directions of the axis. At least one of the first surface and the second surface includes a recessed portion.

Such inclusion of the recessed portion in the coil wiring layer as described above increases a contact area between the coil wiring layer and the insulation layer. As a result, adhesion between the coil wiring layer and the insulation layer increases so that the coil wiring layer and the insulation layer are made to resist separation from each other.

According to the present disclosure, the inductor component by which reduction in the separation of the coil wiring layer and the insulation layer has been achieved can be provided.

### BRIEF DESCRIPTION OF THE DRAWINGS

FIG. 1 is a perspective view of an inductor component of a first embodiment;

FIG. 2 is a transparent elevational view of the inductor component of FIG. 1;

FIG. 3 is a sectional view along III-III of the inductor component of FIG. 2;

FIG. 4A is an exploded view of the inductor component of FIG. 1;

FIG. 4B is an exploded view of the inductor component of FIG. 1;

FIG. 5 is a partial enlarged view of FIG. 3;

FIG. 6 is an XZ sectional view of an inductor component of a second embodiment;

FIG. 7 is a partial enlarged view of FIG. 6;

FIG. 8 is a partial exploded view of an inductor component of a third embodiment; and

FIG. 9 is an YZ sectional view of FIG. 8.

### DETAILED DESCRIPTION

Hereinbelow, an inductor component that is an aspect of the present disclosure will be described in detail with reference to aspects of embodiments illustrated in the drawings. Incidentally, the drawings may include schematic ones and may lack reflection of actual sizes or proportions.

### First Embodiment

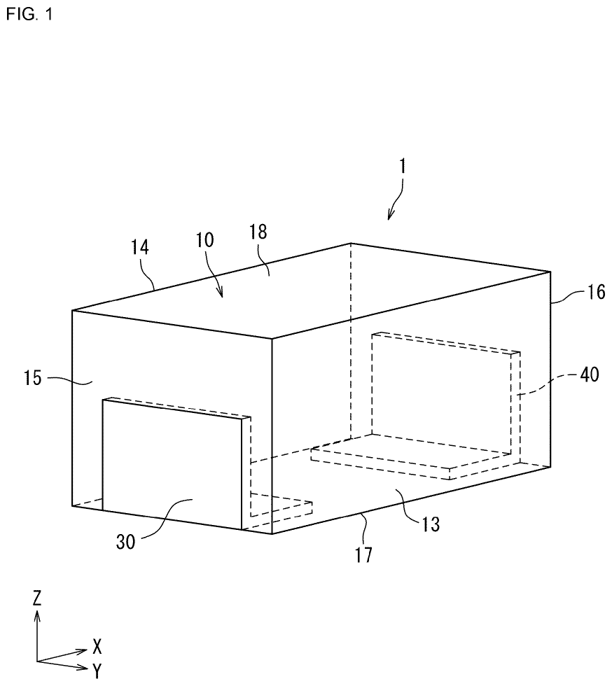

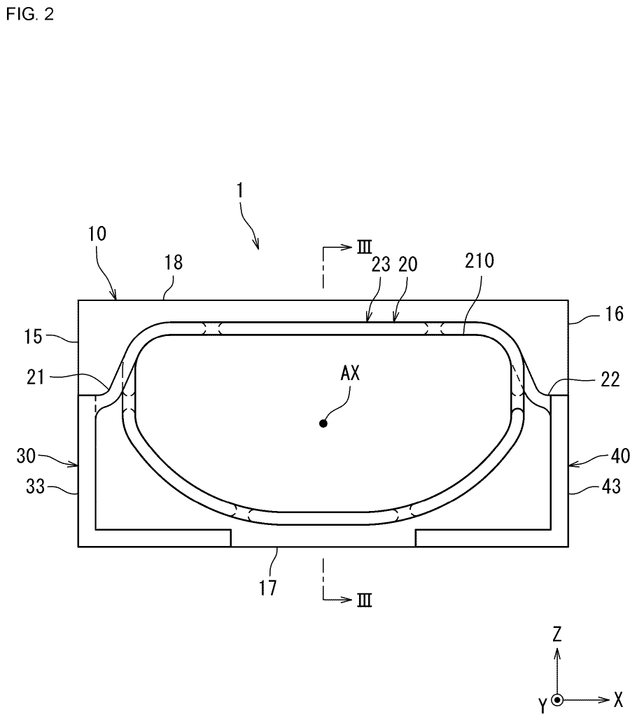

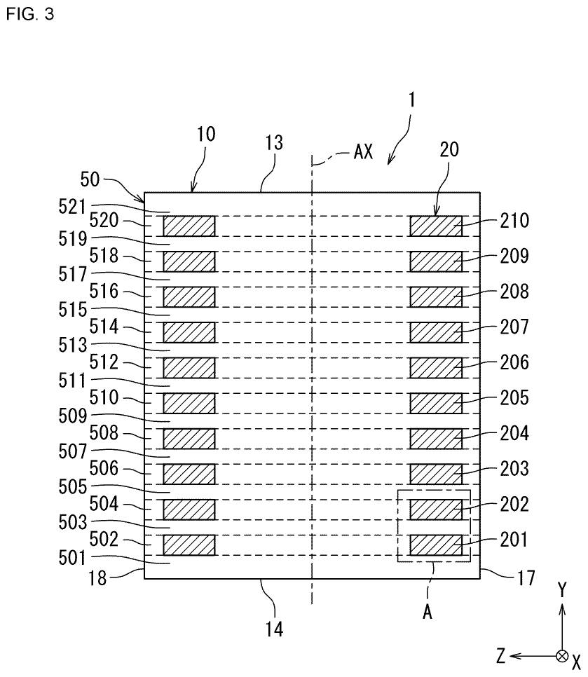

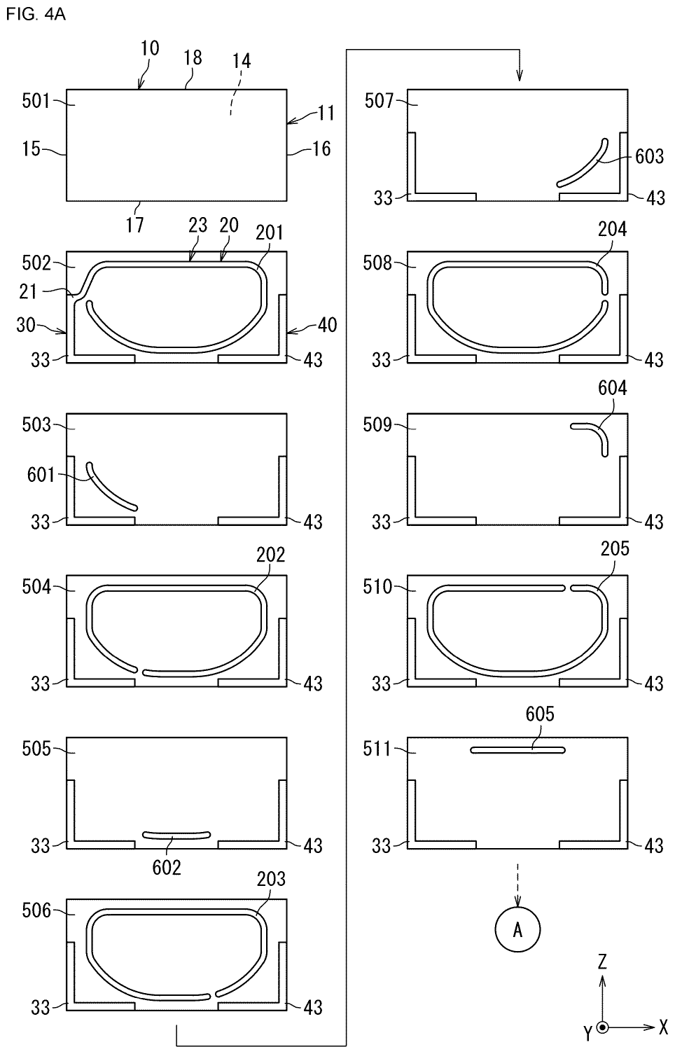

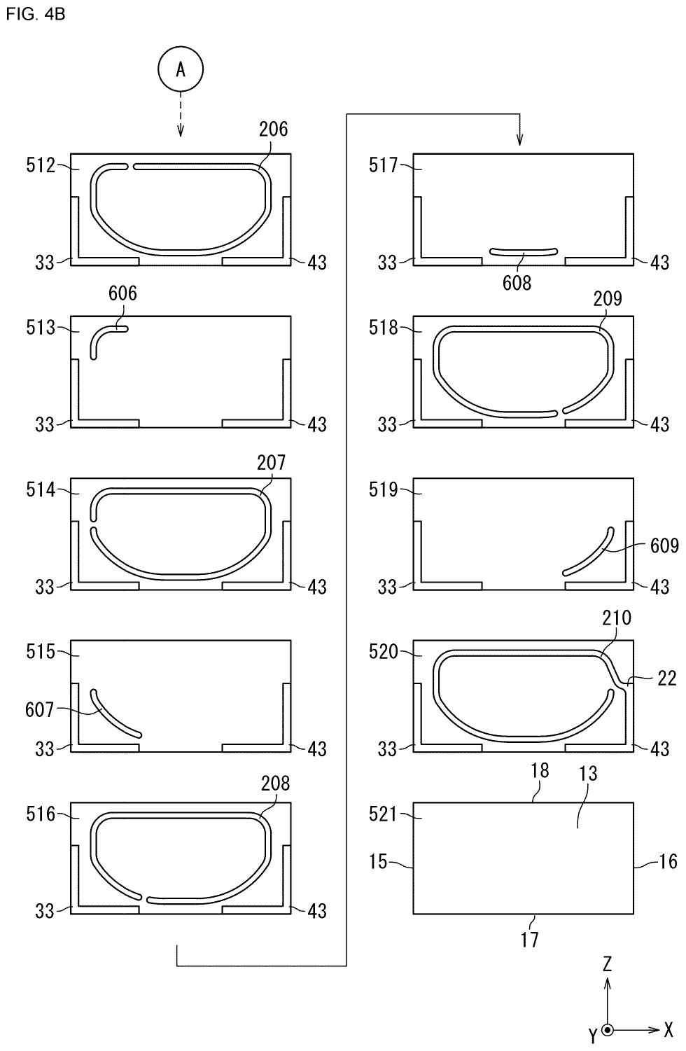

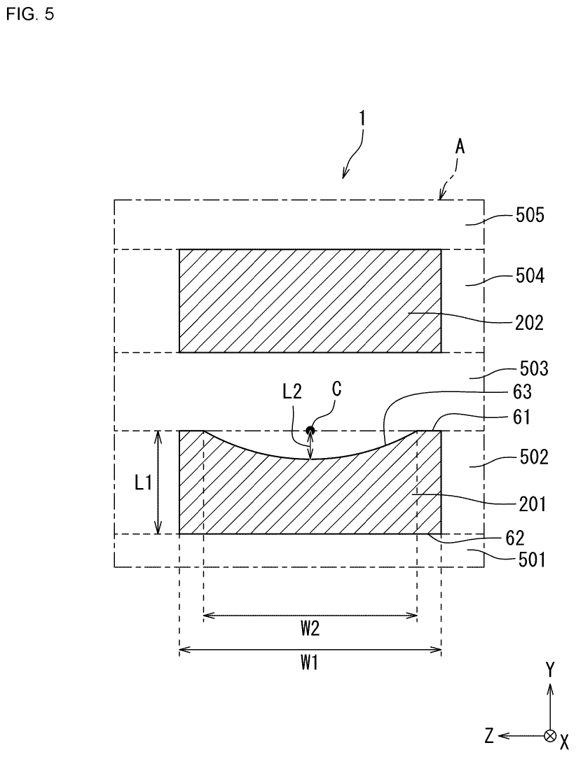

FIG. 1 is an incline view illustrating a first embodiment of the inductor component. FIG. 2 is a transparent elevational view of the inductor component of FIG. 1. FIG. 3 is a sectional view along III-III of FIG. 2. FIGS. 4A and 4B are exploded views of the inductor component of FIG. 1. FIG. 5 is a partial enlarged view of FIG. 3. Incidentally, illustration in FIG. 2 is made with transparency for convenience and for facilitation of understanding of a structure, whereas the illustration may be made with translucency or opacity. Further, in FIG. 3, via wiring layers are not illustrated for facilitation of understanding of a structure.

As illustrated in FIGS. 1, 2, and 3, an inductor component 1 is electrically connected to wiring of a circuit board not illustrated, with first and second outer electrodes 30 and 40 interposed therebetween. The inductor component 1 is used as a coil for impedance matching (matching coil) of a high-frequency circuit, for instance, and is used for electronic equipment such as personal computer, DVD player, digital camera, TV, cellular phone, car electronics, or medical or industrial machine. Application of the inductor component 1, however, is not limited thereto and the inductor component 1 may be used for a tuned circuit, a filter circuit, a rectifying smoothing circuit, or the like, for instance.

An element body 10 is substantially shaped like a rectangular parallelepiped. Surfaces of the element body 10 include a first end surface 15 and a second end surface 16 that are opposed to each other, a first side surface 13 and a second side surface 14 that are opposed to each other, a bottom surface 17 connected between the first end surface 15 and the second end surface 16 and between the first side surface 13 and the second side surface 14, and a top surface 18 opposed to the bottom surface 17. The bottom surface 17 is a surface that is to front on a side of a mount board, not illustrated, when the inductor component 1 is mounted on the mount board.

As illustrated, X direction is a direction orthogonal to the first end surface 15 and the second end surface 16 and oriented from the first end surface 15 toward the second end surface 16. Y direction is a direction orthogonal to the first side surface 13 and the second side surface 14 and oriented from the second side surface 14 toward the first side surface 13. Z direction is a direction orthogonal to the bottom surface 17 and the top surface 18 and oriented from the bottom surface 17 toward the top surface 18. X direction may be referred to as a length direction for the element body 10, Y direction may be referred to as a width direction for the element body 10, and Z direction may be referred to as a height direction for the element body 10. X direction, Y direction, and Z direction are orthogonal to one another and configure a left-handed system by being sequenced in order of X, Y, and Z.

The first outer electrode 30 and the second outer electrode 40 include conductive material such as Ag, Cu, Au, or alloy including those as major ingredients, for instance. Further, the first outer electrode 30 and the second outer electrode 40 may include the above-described conductive material (Ag, Cu, Au, for instance) as a foundation layer, an Ni plated layer, and an Sn plated layer, in order of mention. In this configuration, the Ni plated layer and the Sn plated layer may be raised from a surface of the element body 10 so as to cover the foundation layer. The first outer electrode 30 has a shape of a letter L formed on an area from the first end surface 15 to the bottom surface 17. The first outer electrode 30 is embedded in the element body 10 so as to be exposed from the first end surface 15 and the bottom surface 17. The second outer electrode 40 has a shape of a letter L formed on an area from the second end surface 16 to the bottom surface 17. The second outer electrode 40 is embedded in the element body 10 so as to be exposed from the second end surface 16 and the bottom surface 17.

Incidentally, though the first outer electrode 30 and the second outer electrode 40 have the shapes of the letter L in the first embodiment, the first outer electrode 30 and the second outer electrode 40 may have other shapes. For instance, the first outer electrode 30 and the second outer electrode 40 may have shapes provided only on the bottom surface. Alternatively, the first outer electrode 30 may be provided on the first end surface 15 of the element body 10 and on portions of the first side surface 13, the second side surface 14, the bottom surface 17, and the top surface 18 that adjoin the first end surface 15, and the second outer electrode 40 may be provided on the second end surface 16 and on portions of the first side surface 13, the second side surface 14, the bottom surface 17, and the top surface 18 that adjoin the second end surface 16.

The first outer electrode 30 and the second outer electrode 40 have a configuration in which a plurality of first outer electrode conductor layers 33 and second outer electrode conductor layers 43 that are embedded in the element body 10 are stacked, respectively. The first outer electrode conductor layers 33 extend along the first end surface 15 and the bottom surface 17 and the second outer electrode conductor layers 43 extend along the second end surface 16 and the bottom surface 17. Thus, the first and second outer electrodes 30, 40 can be embedded in the element body 10, so that miniaturization of the inductor component can be pursued compared with a configuration in which outer electrodes are externally mounted on the element body 10. Further, a coil 20 and the first and second outer electrodes 30, 40 can be formed in one and same step, so that variation in electrical characteristics of the inductor component 1 can be reduced with reduction in variation in positional relation among the coil 20 and the first and second outer electrodes 30, 40.

The coil 20 includes conductive material similar to the material of the first and second outer electrodes 30, 40, for instance. A first end of the coil 20 is connected to the first outer electrode 30 and a second end of the coil 20 is connected to the second outer electrode 40. Incidentally, though the coil 20 and the first and second outer electrodes 30, 40 are integrated and have no clearly defined boundaries in the present embodiment, there is no limitation thereto and the boundaries may exist due to formation of the coil and the outer electrodes with dissimilar materials or dissimilar techniques.

An axis AX of the coil 20 is parallel to the bottom surface 17 and intersects with the first side surface 13 and the second side surface 14. The coil 20 is wound along the axis AX. The axis AX of the coil 20 coincides with Y direction. The axis AX of the coil 20 means a center axis of a helical shape of the coil 20.

The coil 20 includes a wound portion 23, a first extended portion 21 connected between a first end of the wound portion 23 and the first outer electrode 30, and a second extended portion 22 connected between a second end of the wound portion 23 and the second outer electrode 40. Though the wound portion 23 and the first and second extended portions 21, 22 are integrated and have no clearly defined boundaries in the present embodiment, there is no limitation thereto and the boundaries may exist due to formation of the wound portion and the extended portions with dissimilar materials or dissimilar techniques.

The wound portion 23 is wound in a shape of a helix along the axis AX. That is, the wound portion 23 refers to a portion in which the coil 20 overlaps with itself as seen looking in a direction parallel to the axis AX and which is wound in the shape of the helix. The first and second extended portions 21, 22 refer to portions that deviate from the overlapping portion. The wound portion 23 is substantially shaped like a rectangle as seen looking in a direction of the axis AX, whereas there is no limitation to that shape. The shape of the wound portion 23 may be like a circle, an oval, a different polygon, or the like, for instance.

The element body 10 includes an insulator 50 and the insulator 50 includes a plurality of stacked insulation layers. Specifically, the element body 10 is configured by sequential stacking of first to twenty-first insulation layers 501 to 521 in the direction from the second side surface 14 toward the first side surface 13. Incidentally, in the present application, stacking is not limited to stacking in the direction of stacking in manufacturing but includes stacking in a direction opposed thereto.

The first to twenty-first insulation layers 501 to 521 include material containing borosilicate glass as a major ingredient, or material such as ferrite or resin, for instance.

The stacking direction of the first to twenty-first insulation layers 501 to 521 is a direction (Y direction) parallel to the first and second end surfaces 15, 16 and the bottom surface 17 of the element body 10 and coincides with the axis AX of the coil 20. That is, the first to twenty-first insulation layers 501 to 521 are shaped like layers extending on XZ plane. Incidentally, the stacking direction in the present application refers to the direction of stacking in the manufacturing. The term “parallel” in the present application is not limited to strictly parallel relation but encompasses substantially parallel relation in consideration of a realistic range of variation. Incidentally, in the element body 10, interfaces between the first to twenty-first insulation layers 501 to 521 may be made vague as a result of firing or the like.

As illustrated in FIGS. 3, 4A, and 4B, the coil 20 includes a plurality of coil wiring layers 201 to 210 stacked along the axis AX and first to ninth via wiring layers 601 to 609 extending along the axis AX and making connections between the coil wiring layers adjoining in directions of the axis AX. Incidentally, in FIGS. 4A and 4B, a direction from an upper left portion toward a lower right portion is defined as the stacking direction (Y direction).

The plurality of coil wiring layers 201 to 210 are each interposed between the insulation layers and are sequentially stacked along the direction of the axis AX (Y direction). That is, the stacking direction of the insulation layers is identical to the direction of the axis AX. Specifically, the first coil wiring layer 201 is interposed between the first insulation layer 501 and the third insulation layer 503. The second coil wiring layer 202 is interposed between the third insulation layer 503 and the fifth insulation layer 505. The third coil wiring layer 203 is interposed between the fifth insulation layer 505 and the seventh insulation layer 507. The fourth coil wiring layer 204 is interposed between the seventh insulation layer 507 and the ninth insulation layer 509. The fifth coil wiring layer 205 is interposed between the ninth insulation layer 509 and the eleventh insulation layer 511. The sixth coil wiring layer 206 is interposed between the eleventh insulation layer 511 and the thirteenth insulation layer 513. The seventh coil wiring layer 207 is interposed between the thirteenth insulation layer 513 and the fifteenth insulation layer 515. The eighth coil wiring layer 208 is interposed between the fifteenth insulation layer 515 and the seventeenth insulation layer 517. The ninth coil wiring layer 209 is interposed between the seventeenth insulation layer 517 and the nineteenth insulation layer 519. The tenth coil wiring layer 210 is interposed between the nineteenth insulation layer 519 and the twenty-first insulation layer 521.

The first to tenth coil wiring layers 201 to 210 are wound along respective planes. Numbers of windings of the first to tenth coil wiring layers 201 to 210 are less than one, whereas the numbers of windings may be one or more.

The coil wiring layers adjoining in the stacking direction are electrically connected in series with the respective first to ninth via wiring layers 601 to 609 interposed therebetween. Specifically, the first coil wiring layer 201 is connected to the second coil wiring layer 202 with the first via wiring layer 601, piercing the third insulation layer 503, interposed therebetween. The second coil wiring layer 202 is connected to the third coil wiring layer 203 with the second via wiring layer 602, piercing the fifth insulation layer 505, interposed therebetween. The third coil wiring layer 203 is connected to the fourth coil wiring layer 204 with the third via wiring layer 603, piercing the seventh insulation layer 507, interposed therebetween. The fourth coil wiring layer 204 is connected to the fifth coil wiring layer 205 with the fourth via wiring layer 604, piercing the ninth insulation layer 509, interposed therebetween. The fifth coil wiring layer 205 is connected to the sixth coil wiring layer 206 with the fifth via wiring layer 605, piercing the eleventh insulation layer 511, interposed therebetween. The sixth coil wiring layer 206 is connected to the seventh coil wiring layer 207 with the sixth via wiring layer 606, piercing the thirteenth insulation layer 513, interposed therebetween. The seventh coil wiring layer 207 is connected to the eighth coil wiring layer 208 with the seventh via wiring layer 607, piercing the fifteenth insulation layer 515, interposed therebetween. The eighth coil wiring layer 208 is connected to the ninth coil wiring layer 209 with the eighth via wiring layer 608, piercing the seventeenth insulation layer 517, interposed therebetween. The ninth coil wiring layer 209 is connected to the tenth coil wiring layer 210 with the ninth via wiring layer 609, piercing the nineteenth insulation layer 519, interposed therebetween. With the above configuration, the plurality of coil wiring layers 201 to 210 configure a helix while being electrically connected in series to one another. Incidentally, though the first to ninth via wiring layers 601 to 609 have shapes like arcs and straight lines as illustrated in FIGS. 4A and 4B in the above aspect of embodiment, the first to ninth via wiring layers 601 to 609 may have other shapes and may have circular shapes, for instance.

The first insulation layer 501 includes the second side surface 14 of the element body 10 and has a surface, opposed to the second side surface 14, in contact with the second insulation layer 502. The first coil wiring layer 201 is connected to the first outer electrode conductor layers 33 with the first extended portion 21 interposed therebetween. The first coil wiring layer 201 is provided in the same layer as the second insulation layer 502 on the first insulation layer 501. The second coil wiring layer 202 is provided in the same layer as the fourth insulation layer 504 orthogonal to the directions of the axis AX, on the third insulation layer 503. The third coil wiring layer 203 is provided in the same layer as the sixth insulation layer 506 orthogonal to the directions of the axis AX, on the fifth insulation layer 505. The fourth coil wiring layer 204 is provided in the same layer as the eighth insulation layer 508 orthogonal to the directions of the axis AX, on the seventh insulation layer 507. The fifth coil wiring layer 205 is provided in the same layer as the tenth insulation layer 510 orthogonal to the directions of the axis AX, on the ninth insulation layer 509. The sixth coil wiring layer 206 is provided in the same layer as the twelfth insulation layer 512 orthogonal to the directions of the axis AX, on the eleventh insulation layer 511. The seventh coil wiring layer 207 is provided in the same layer as the fourteenth insulation layer 514 orthogonal to the directions of the axis AX, on the thirteenth insulation layer 513. The eighth coil wiring layer 208 is provided in the same layer as the sixteenth insulation layer 516 orthogonal to the directions of the axis AX, on the fifteenth insulation layer 515. The ninth coil wiring layer 209 is provided in the same layer as the eighteenth insulation layer 518 orthogonal to the directions of the axis AX, on the seventeenth insulation layer 517. The tenth coil wiring layer 210 is provided in the same layer as the twentieth insulation layer 520 orthogonal to the directions of the axis AX, on the nineteenth insulation layer 519. The tenth coil wiring layer 210 is connected to the second outer electrode conductor layers 43 with the second extended portion 22 interposed therebetween.

The first outer electrode conductor layers 33 are provided in the area from the first end surface 15 to the bottom surface 17 on the second to twentieth insulation layers 502 to 520. The second outer electrode conductor layers 43 are provided in the area from the second end surface 16 to the bottom surface 17 on the second to twentieth insulation layers 502 to 520.

FIG. 5 illustrates a partial enlarged view of a portion A of FIG. 3. As illustrated in FIG. 5, the first coil wiring layer 201 includes a first surface 61 positioned in one of the directions of the axis AX and a second surface 62 positioned in the other of the directions of the axis AX and opposed to the first surface 61. In this embodiment, the one of the directions of the axis AX is the stacking direction and, specifically, is Y direction (direction from the second side surface 14 toward the first side surface 13). The other of the directions of the axis AX is a direction opposed to Y direction.

The first surface 61 is in contact with the third insulation layer 503. The first surface 61 includes a recessed portion 63. The recessed portion 63 is in contact with the third insulation layer 503. The second surface 62 is in contact with the first insulation layer 501. The first surface 61 including the recessed portion 63 increases a contact area between the first coil wiring layer 201 and the third insulation layer 503, compared with the first surface 61 being a flat surface. As a result, adhesion between the first coil wiring layer 201 and the third insulation layer 503 increases so that the first coil wiring layer 201 and the third insulation layer 503 may be made to resist separation from each other even if thermal stresses or bending stresses occur, for instance. Though the first surface 61 includes the recessed portion 63 in the first embodiment, the second surface 62 may include the recessed portion 63, or the first surface 61 may include the recessed portion 63 and the second surface 62 may also include the recessed portion 63.

Incidentally, the recessed portion 63 is not illustrated in FIGS. 3, 4A, and 4B. Further, there may be one recessed portion 63 or there may be a plurality of recessed portions 63. The recessed portion may extend along a whole length of the coil wiring layer in an extending direction or may be partially placed or a plurality of recessed portions may be separately placed. The recessed portion 63 may exist on at least one of the first to tenth coil wiring layers 201 to 210.

As illustrated in FIG. 5, the recessed portion 63 preferably exists at a center C of a width of the first coil wiring layer 201 in a direction orthogonal to the axis AX, in a section orthogonal to the extending direction of the first coil wiring layer 201. With the above configuration, a length in the directions of the axis AX of a surface (inner peripheral surface of the coil) of the first coil wiring layer 201 on a side of the axis AX can be increased so that a thickness of the coil 20 on an inner periphery side can be increased. Thus, a path of a current can be enlarged. Accordingly, a loss of the current can be decreased and Q value can be increased. Incidentally, “center” in the present application is not limited to a strict center position but includes substantial center positions in consideration of a realistic range of variation. For instance, deviations from the strict center position by ±20% of the width of the coil wiring layer in the direction orthogonal to the axis are included as well.

In the section orthogonal to the extending direction of the first coil wiring layer 201 as illustrated in FIG. 5, a depth L2 of the recessed portion 63 in the directions of the axis AX is in a range from 5% or more to 30% or less (i.e., from 5% to 30%) of a thickness L1 of the first coil wiring layer 201 in the directions of the axis AX, preferably in a range from 5% or more to 25% or less (i.e., from 5% to 25%) thereof, and more preferably in a range from 5% or more to 20% or less (i.e., from 5% to 20%) thereof. Separation between the first coil wiring layer 201 and the third insulation layer 503 can be curbed with the depth L2 greater than or equal to a lower limit relative to the thickness L1. With the depth L2 smaller than or equal to an upper limit relative to the thickness L1, further, the thickness of the first coil wiring layer 201 can be increased and an electrical resistance Rdc can be lowered.

Herein, the thickness L1 of the first coil wiring layer 201 in the directions of the axis AX has a measured value of a thickness of the first coil wiring layer 201 exposed by polishing of a section parallel to the axis AX and perpendicular to an extending direction of the coil 20. The depth L2 of the recessed portion 63 in the directions of the axis AX has a value measured as with the thickness L1.

Incidentally, the thickness L1 of the first coil wiring layer 201 in the directions of the axis AX refers to a maximum value of sizes of the first coil wiring layer 201 in a direction along the axis AX in sections orthogonal to the extending direction of the first coil wiring layer 201. The depth L2 of the recessed portion 63 in the directions of the axis AX is of a deepest site in the direction along the directions of the axis AX. On condition that a plurality of recessed portions 63 exist, the depth L2 of the recessed portions 63 in the directions of the axis AX means a value of the deepest recessed portion 63.

In the section orthogonal to the extending direction of the first coil wiring layer 201, as illustrated in FIG. 5, a width W2 of the recessed portion 63 in the direction orthogonal to the axis AX is in a range from 40% or more to 80% or less (i.e., from 40% to 80%) of a width W1 of the first coil wiring layer 201 in the direction orthogonal to the axis AX, preferably in a range from 50% or more to 80% or less (i.e., from 50% to 80%) thereof, and more preferably in a range from 60% or more to 75% or less (i.e., from 60% to 75%) thereof. With the width W2 greater than or equal to a lower limit relative to the width W1, and with the first surface 61 including the recessed portion 63, the contact area between the first coil wiring layer 201 and the third insulation layer 503 is increased compared with the first surface 61 being a flat surface. As a result, the adhesion between the first coil wiring layer 201 and the third insulation layer 503 increases so that the first coil wiring layer 201 and the third insulation layer 503 may be made to resist the separation from each other. With the width W2 smaller than or equal to an upper limit relative to the width W1, a cross-sectional area of the inductor component 1 can be ensured and the electrical resistance Rdc can be lowered.

Herein, the width W1 of the first coil wiring layer 201 in the direction orthogonal to the axis AX refers to a maximum value of lengths in the direction orthogonal to the axis AX between the first surface 61 and the second surface 62, in the sections orthogonal to the extending direction of the first coil wiring layer 201. The width W2 of the recessed portion 63 in the direction orthogonal to the axis AX refers to a maximum value of widths of the recessed portion 63 in the sections orthogonal to the extending direction of the first coil wiring layer 201. Incidentally, on condition that a plurality of recessed portions 63 exist in the section orthogonal to the extending direction of the first coil wiring layer 201, the width W2 of the recessed portions 63 refers to a total for the plurality of recessed portions 63.

The width W1 of the first coil wiring layer 201 in the direction orthogonal to the axis AX has a measured value of a width of the first coil wiring layer 201 exposed by polishing of a section perpendicular to the axis AX and perpendicular to the extending direction of the coil 20. The width W2 of the recessed portion 63 in the direction orthogonal to the axis AX has a value measured as with the width W1.

Incidentally, the recessed portion 63 does not have to be at the center C of the width of the first coil wiring layer 201 in the direction orthogonal to the axis AX, in a section orthogonal to the extending direction of the first coil wiring layer 201. For instance, the recessed portion 63 may exist on a side of the inner peripheral surface with respect to the width direction or on a side of an outer peripheral surface with respect to the width direction. A value of the depth L2 relative to the thickness L1 may be less than 5% or more than 30%. A value of the width W2 relative to the width W1 may be less than 40% or more than 80%.

### Method of Manufacturing Inductor Component 1

From an upper side toward a lower side as illustrated in FIG. 4A, the first coil wiring layer 201 is provided on the first insulation layer 501, and the first via wiring layer 601, the second coil wiring layer 202, the second via wiring layer 602, the third coil wiring layer 203, the third via wiring layer 603, the fourth coil wiring layer 204, the fourth via wiring layer 604, the fifth coil wiring layer 205, and the fifth via wiring layer 605 are stacked thereon in order of mention, and, from an upper side toward a lower side as illustrated in FIG. 4B, the sixth coil wiring layer 206, the sixth via wiring layer 606, the seventh coil wiring layer 207, the seventh via wiring layer 607, the eighth coil wiring layer 208, the eighth via wiring layer 608, the ninth coil wiring layer 209, the ninth via wiring layer 609, and the tenth coil wiring layer 210 are subsequently stacked thereon in order of mention, and the twenty-first insulation layer 521 is stacked on the tenth coil wiring layer 210. Thus, the inductor component 1 is manufactured.

The first to tenth coil wiring layers 201 to 210 are provided on the respective insulation layers by screen printing, for instance.

The recessed portion 63 is formed on the first surface 61 of the first coil wiring layer 201 by laser processing, mechanical processing such as grinding processing, or chemical processing such as etching, for instance. Thus, the recessed portion 63 is formed under control. Incidentally, the recessed portion 63 may be similarly provided on the second to tenth coil wiring layers 202 to 210 or may be provided on at least one of the first to tenth coil wiring layers 201 to 210. Further, the recessed portion 63 may be formed by a processing method other than the above-mentioned mechanical processing or chemical processing.

The first to ninth via wiring layers 601 to 609 are provided in cavities on the insulation layers by screen printing, for instance, after provision of the cavities on the insulation layers by a photolithographic technique or a laser technique, for instance.

### Second Embodiment

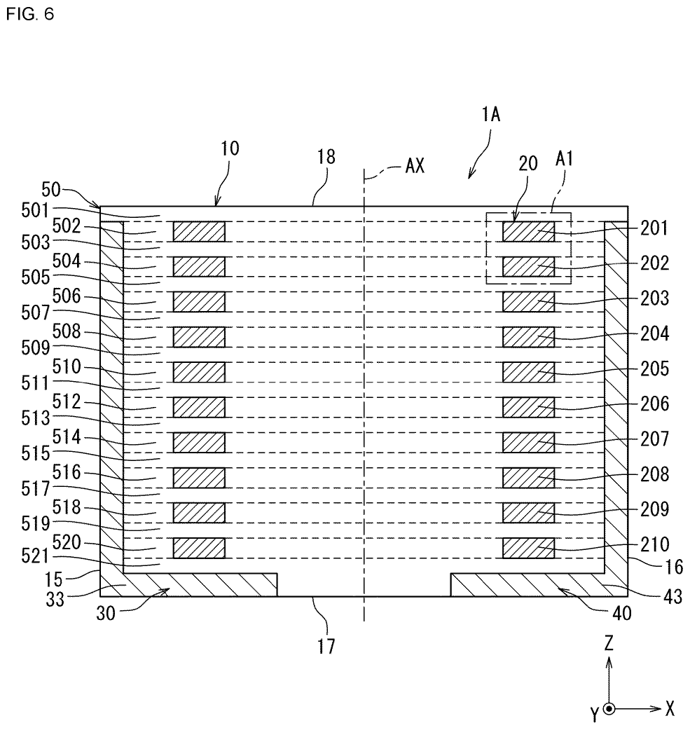

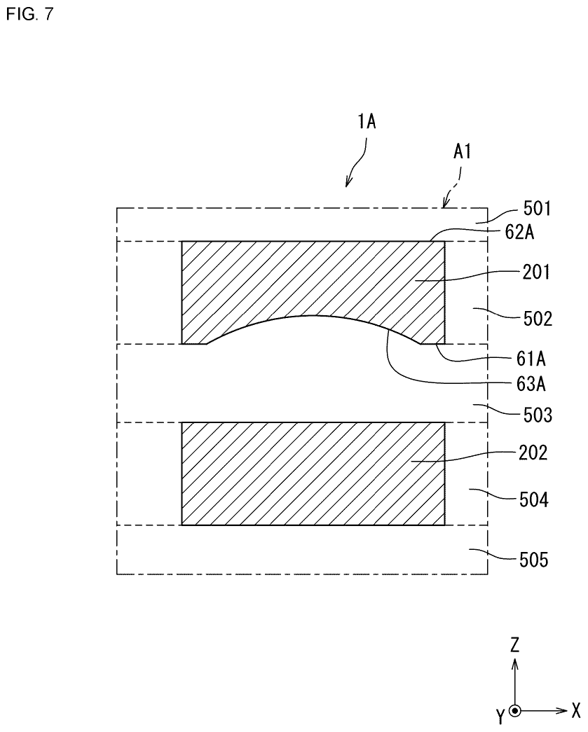

FIG. 6 is an XZ sectional view of an inductor component 1A. FIG. 7 is a partial enlarged view of FIG. 6. A second embodiment differs from the first embodiment in directions of an axis of a coil. This different configuration will be described below. The other configurations are the same as those of the first embodiment and description thereof is omitted.

As illustrated in FIG. 6, the element body 10 is configured by sequential stacking of the first to twenty-first insulation layers 501 to 521 in manufacturing in a direction (direction opposed to Z direction) from the top surface 18 toward the bottom surface 17.

The axis AX of the coil 20 is provided so as to be parallel to the first end surface 15 and so as to intersect with the bottom surface 17 and the top surface 18. Inclusion of the above configuration enables diverse options for the inductor component 1A.

The coil 20 includes the plurality of coil wiring layers 201 to 210 stacked along the directions of the axis AX and the first to ninth via wiring layers 601 to 609 extending along the axis AX and making connections between the coil wiring layers adjoining in the directions of the axis AX.

As illustrated in FIG. 7, the first coil wiring layer 201 includes a first surface 61A positioned in one of the directions of the axis AX and a second surface 62A positioned in the other of the directions of the axis AX and opposed to the first surface 61A. In this embodiment, the one of the directions of the axis AX is the stacking direction in the manufacturing and, specifically, is the direction opposed to Z direction (direction from the top surface 18 toward the bottom surface 17). The other of the directions of the axis AX is Z direction.

A recessed portion 63A of the first coil wiring layer 201 preferably exists on the first surface 61A, positioned on a side of the bottom surface 17, of the first surface 61A and the second surface 62A. Inclusion of the above configuration facilitates formation of the recessed portion on the first coil wiring layer 201 in the stacking.

The first outer electrode 30 has a shape of a letter L formed on an area from the first end surface 15 to the bottom surface 17. The second outer electrode 40 has a shape of a letter L formed on an area from the second end surface 16 to the bottom surface 17.

### Third Embodiment

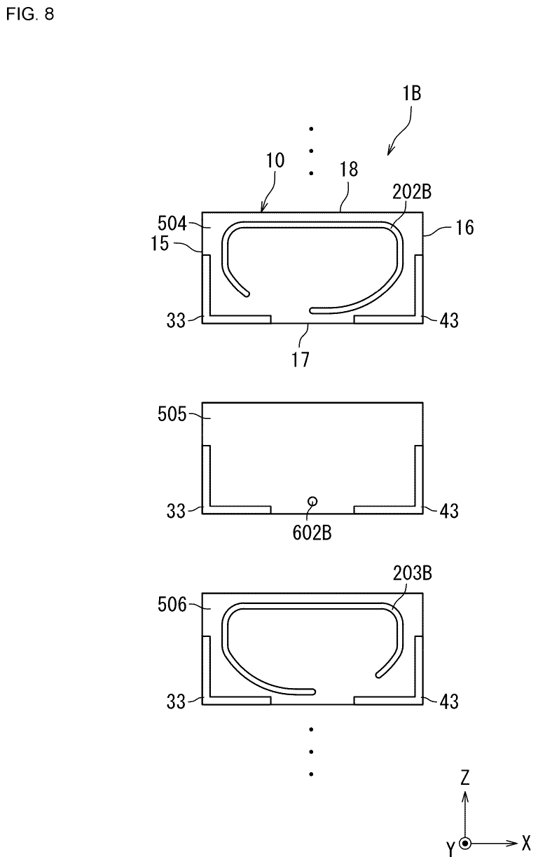

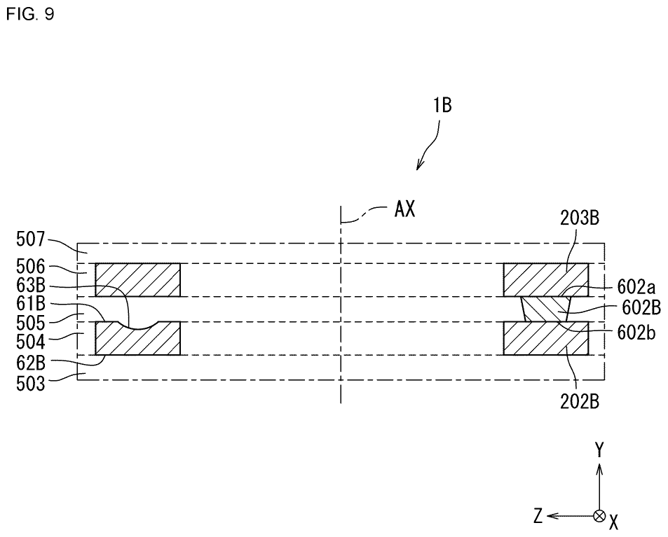

FIG. 8 is an exploded plan view of an inductor component 1B. FIG. 9 is a YZ sectional view of the inductor component 1B. A third embodiment differs from the first embodiment in that the via wiring layers of the first embodiment are replaced by via conductors. This different configuration will be described below. The other configurations are the same as those of the first embodiment and description thereof is omitted.

As illustrated in FIG. 8, a plurality of coil wiring layers of the third embodiment are each interposed between insulation layers and are sequentially stacked along a direction of the axis AX (Y direction) as with the plurality of coil wiring layers 201 to 210 of the first embodiment. Lengths of the first to tenth coil wiring layers of the third embodiment are shorter than respective lengths of the first to tenth coil wiring layers of the first embodiment. Incidentally, FIG. 8 illustrates only the second coil wiring layer 202B and the third coil wiring layer 203B among the coil wiring layers.

The coil wiring layers adjoining in the stacking direction are electrically connected in series with first to ninth via conductors interposed therebetween. Incidentally, FIG. 8 illustrates only a second via conductor 602B.

As illustrated in FIG. 9, a width of a first surface 602a of the second via conductor 602B in one of the directions of the axis AX is wider than a width of a second surface 602b of the second via conductor 602B in the other of the directions of the axis AX. The one of the directions of the axis AX is the stacking direction in the manufacturing and, specifically, is Y direction. The other of the directions of the axis AX is the direction opposed to Y direction. That is, an area of the first surface 602a of the second via conductor 602B on a side of the third coil wiring layer 203B in the directions of the axis AX is wider than an area of the second surface 602b of the second via conductor 602B on a side of the second coil wiring layer 202B in the directions of the axis AX. Inclusion of the above configuration enables diverse options for the inductor component 1B. The second via conductor 602B is a tapered conductor in which side surfaces of a via are tilted so that widths of the via narrow from the first surface 602a toward the second surface 602b. Incidentally, side surfaces of the second via conductor 602B may include convexly curved surfaces or may include concavely curved surfaces.

The second coil wiring layer 202B includes a first surface 61B in one (on a side of the third coil wiring layer 203B) of the directions of the axis AX and a second surface 62B in the other (on a side opposed to the first surface 61B) of the directions of the axis AX. A recessed portion 63B is provided on the first surface 61B of the second coil wiring layer 202B. A recessed portion may be provided on surfaces of other coil wiring layers on one side with respect to the axis AX.

As illustrated in FIGS. 8 and 9, the second via conductor 602B can be formed as follows. Initially, the second coil wiring layer 202B is provided. Further, the recessed portion 63B is provided on the first surface 61B of the second coil wiring layer 202B by laser processing, mechanical processing such as grinding processing, or chemical processing such as etching. The recessed portion 63B is provided at a position different from a position that is to be in contact with the second via conductor 602B. Subsequently, the fifth insulation layer 505 is provided on the second coil wiring layer 202B and the fourth insulation layer 504. Further, a through-hole is provided on the fifth insulation layer 505 by laser processing or mechanical processing such as grinding processing, and the second via conductor 602B is provided in the through-hole. Thus, the second via conductor 602B and the second coil wiring layer 202B are connected. By provision of the through-hole such that an opening on a side of the third coil wiring layer 203B is larger than an opening on a side of the second coil wiring layer 202B, the area of the first surface 602a of the second via conductor 602B can be made larger than the area of the second surface 602b of the second via conductor 602B. Subsequently, the third coil wiring layer 203B is provided so as to be coupled to the second via conductor 602B. Incidentally, the recessed portion 63B may be formed by a processing method other than the above-mentioned mechanical processing or chemical processing.

Incidentally, the present disclosure is not limited to the embodiments described above and design thereof can be modified without departing from the purport of the present disclosure. For instance, characteristic points of the first to third embodiments may be combined variously.

The present disclosure includes following aspects.

<1> An inductor component including an element body; a coil provided in the element body and wound along an axis; and a first outer electrode and a second outer electrode that are provided on the element body and that are electrically connected to the coil. The element body includes a plurality of insulation layers. The coil includes a plurality of coil wiring layers stacked along directions of the axis. The coil wiring layers are each interposed between the insulation layers. At least one of the coil wiring layers includes a first surface positioned in one of the directions of the axis and a second surface positioned in the other of the directions of the axis. Also, at least one of the first surface and the second surface includes a recessed portion.

<2> The inductor component according to <1>, in which the recessed portion exists on only one of the first surface and the second surface.

<3> The inductor component according to <1> or <2>, in which the recessed portion exists at a center of a width of the coil wiring layer in a direction orthogonal to the axis, in a section orthogonal to an extending direction of the coil wiring layer.

<4> The inductor component according to any one of <1> to <3>, in which a depth of the recessed portion in the directions of the axis is in a range from 5% or more to 30% or less (i.e., from 5% to 30%) of a thickness of the coil wiring layer in the directions of the axis, in a section orthogonal to an extending direction of the coil wiring layer.

<5> The inductor component according to any one of <1> to <4>, in which a width of the recessed portion in a direction orthogonal to the axis is in a range from 40% or more to 80% or less (i.e., from 40% to 80%) of a width of the coil wiring layer in the direction orthogonal to the axis, in a section orthogonal to an extending direction of the coil wiring layer.

<6> The inductor component according to any one of <1> to <5>, in which the element body includes a first end surface and a second end surface that are opposed to each other, a first side surface and a second side surface that are opposed to each other, a bottom surface connected between the first end surface and the second end surface and between the first side surface and the second side surface, and a top surface opposed to the bottom surface. Also, the axis is provided so as to be parallel to the bottom surface and so as to intersect with the first side surface and the second side surface, the first outer electrode extends along at least the bottom surface, and the second outer electrode extends along at least the bottom surface.

<7> The inductor component according to any one of <1> to <6>, in which the element body includes a first end surface and a second end surface that are opposed to each other, a first side surface and a second side surface that are opposed to each other, a bottom surface connected between the first end surface and the second end surface and between the first side surface and the second side surface, and a top surface opposed to the bottom surface. Also, the axis is provided so as to be parallel to the first end surface and so as to intersect with the bottom surface and the top surface, the first outer electrode extends along at least the bottom surface, and the second outer electrode extends along at least the bottom surface.

<8> The inductor component according to <7>, in which the recessed portion exists on only a surface positioned on a side of the bottom surface, of the first surface and the second surface.

<9> The inductor component according to any one of <1> to <8>, in which the plurality of coil wiring layers further include a via conductor to couple two adjoining coil wiring layers, an end surface of the via conductor in the one of the directions of the axis is wider than an end surface of the via conductor in the other of the directions of the axis, and the recessed portion exists on only the first surface.

What is claimed is:

1. An inductor component comprising:
an element body including a plurality of insulation layers;
a coil in the element body and wound along an axis, the coil including a plurality of coil wiring layers stacked along directions of the axis, the coil wiring layers are each interposed between the insulation layers, at least one of the coil wiring layers includes a first surface in one of the directions of the axis and a second surface in an other of the directions of the axis, and at least one of the first surface and the second surface includes a recessed portion; and
a first outer electrode and a second outer electrode that are on the element body and that are electrically connected to the coil.

2. The inductor component according to claim 1, wherein
the recessed portion exists on only one of the first surface and the second surface.

3. The inductor component according to claim 1, wherein
the recessed portion exists at a center of a width of the coil wiring layer in a direction orthogonal to the axis, in a section orthogonal to an extending direction of the coil wiring layer.

4. The inductor component according to claim 1, wherein
a depth of the recessed portion in the directions of the axis is in a range from 5% to 30% of a thickness of the coil wiring layer in the directions of the axis, in a section orthogonal to an extending direction of the coil wiring layer.

5. The inductor component according to claim 1, wherein
a width of the recessed portion in a direction orthogonal to the axis is in a range from 40% to 80% of a width of the coil wiring layer in the direction orthogonal to the axis, in a section orthogonal to an extending direction of the coil wiring layer.

6. The inductor component according to claim 1, wherein
the element body includes a first end surface and a second end surface that are opposed to each other, a first side surface and a second side surface that are opposed to each other, a bottom surface connected between the first end surface and the second end surface and between the first side surface and the second side surface, and a top surface opposed to the bottom surface,
the axis is parallel to the bottom surface and intersects with the first side surface and the second side surface,
the first outer electrode extends along at least the bottom surface, and
the second outer electrode extends along at least the bottom surface.

7. The inductor component according to claim 1, wherein
the element body includes a first end surface and a second end surface that are opposed to each other, a first side surface and a second side surface that are opposed to each other, a bottom surface connected between the first end surface and the second end surface and between the first side surface and the second side surface, and a top surface opposed to the bottom surface,
the axis is parallel to the first end surface and intersects with the bottom surface and the top surface,
the first outer electrode extends along at least the bottom surface, and
the second outer electrode extends along at least the bottom surface.

8. The inductor component according to claim 7, wherein
the recessed portion exists on only a surface positioned on a side of the bottom surface, of the first surface and the second surface.

9. The inductor component according to claim 1, wherein
the plurality of coil wiring layers further include a via conductor to couple two adjoining coil wiring layers,
an end surface of the via conductor in the one of the directions of the axis is wider than an end surface of the via conductor in the other of the directions of the axis, and
the recessed portion exists on only the first surface.

10. The inductor component according to claim 2, wherein
the recessed portion exists at a center of a width of the coil wiring layer in a direction orthogonal to the axis, in a section orthogonal to an extending direction of the coil wiring layer.

11. The inductor component according to claim 2, wherein
a depth of the recessed portion in the directions of the axis is in a range from 5% to 30% of a thickness of the coil wiring layer in the directions of the axis, in a section orthogonal to an extending direction of the coil wiring layer.

12. The inductor component according to claim 2, wherein
a width of the recessed portion in a direction orthogonal to the axis is in a range from 40% to 80% of a width of the coil wiring layer in the direction orthogonal to the axis, in a section orthogonal to an extending direction of the coil wiring layer.

13. The inductor component according to claim 2, wherein
the element body includes a first end surface and a second end surface that are opposed to each other, a first side surface and a second side surface that are opposed to each other, a bottom surface connected between the first end surface and the second end surface and between the first side surface and the second side surface, and a top surface opposed to the bottom surface,
the axis is parallel to the bottom surface and intersects with the first side surface and the second side surface,
the first outer electrode extends along at least the bottom surface, and
the second outer electrode extends along at least the bottom surface.

14. The inductor component according to claim 2, wherein
the element body includes a first end surface and a second end surface that are opposed to each other, a first side surface and a second side surface that are opposed to each other, a bottom surface connected between the first end surface and the second end surface and between the first side surface and the second side surface, and a top surface opposed to the bottom surface,
the axis is parallel to the first end surface and intersects with the bottom surface and the top surface,
the first outer electrode extends along at least the bottom surface, and
the second outer electrode extends along at least the bottom surface.

15. The inductor component according to claim 14, wherein
the recessed portion exists on only a surface positioned on a side of the bottom surface, of the first surface and the second surface.

16. The inductor component according to claim 2, wherein
the plurality of coil wiring layers further include a via conductor to couple two adjoining coil wiring layers,
an end surface of the via conductor in the one of the directions of the axis is wider than an end surface of the via conductor in the other of the directions of the axis, and
the recessed portion exists on only the first surface.
